(19) United States
(12) Patent Application Publication
(10) Pub. No.: US 2013/0119540 A1
(43) Pub. Date: May 16, 2013

(54) SEMICONDUCTOR PACKAGE AND METHOD FOR MANUFACTURING THE SAME

(71) Applicants: Jong Kuk Hong, Gyunggi-do (KR); Keung Jin Sohn, Gyunggi-do (KR); Jung Hwan Park, Gyunggi-go (KR)

(72) Inventors: Jong Kuk Hong, Gyunggi-do (KR); Keung Jin Sohn, Gyunggi-do (KR); Jung Hwan Park, Gyunggi-go (KR)

(73) Assignee: SAMSUNG ELECTRO-MECHANICS CO., LTD., Gyunggi-do (KR)

(21) Appl. No.: 13/362,048

(22) Filed: Jan. 31, 2012

(30) Foreign Application Priority Data
Nov. 16, 2011 (KR) 1020110119697

(51) Int. Cl. H01L 23/498; H01L 21/50; H01L 23/48

(52) U.S. Cl. 257/738; 257/778; 257/734; 438/108; 257/E23.069; 257/E23.01; 257/E21.499

(57) ABSTRACT

Disclosed herein are a semiconductor package and a method for manufacturing the same. The method includes preparing a substrate having one surface and the other surface; mounting a semiconductor device mounted on one surface of the substrate; forming external connection terminals on the other surface of the substrate; forming a warpage preventing layer formed on one surface of the substrate or the other surface of the substrate; and performing a reflow process on the substrate.

### CROSS REFERENCE TO RELATED APPLICATION

This application claims the benefit of Korean Patent Application No. 10-2011-0119697, filed on Nov. 16, 2011, entitled “Semiconductor Package and Manufacturing Method thereof”, which is hereby incorporated by reference in its entirety into this application.

### BACKGROUND OF THE INVENTION

1. Technical Field

The present invention relates to a semiconductor package and a method for manufacturing the same.

2. Description of the Related Art

With the trend for small size and multiple functions of recent electronic devices, there is a growing need for a technology for a small-sized package having high circuit density.

In addition, various package structures have been proposed that, for example, the thicknesses of a chip and a substrate are continuously decreased or a package is again formed on another package as disclosed in Document 1, and the like. However, thermal history during a package mounting process causes package to be defective, and for this reason, a mount warpage control technique is requested.
[Document 1] KR 10-0722634 B 2007 May 21

### SUMMARY OF THE INVENTION

The present invention has been made in an effort to provide a semiconductor package capable of reducing a warpage phenomenon that occurs in substrates or packages at a high temperature when an uncured resin is formed on a substrate and then a high-temperature packaging process such as reflowing is performed, by using cure shrinkage of a resin, and a method for manufacturing the same.

According to one preferred embodiment of the present invention, there is provided a semiconductor package, including: a substrate having one surface and the other surface; a semiconductor device mounted on one surface of the substrate; external connection terminals formed on the other surface of the substrate; and a warpage preventing layer formed on one surface or the other surface of the substrate.

The semiconductor package may be a flip chip chip scale package (FCCSP) type or a flip chip ball grid array (FCBGA) type.

The warpage preventing layer may be made of a cure shrinkable material.

The warpage preventing layer may be made of a resin.

The warpage preventing layer may be formed on the outermost layer of the substrate.

According to another preferred embodiment of the present invention, there is provided a semiconductor package, including: a top package having one surface and the other surface and including a semiconductor device mounted thereon; external connection terminals formed on one surface of the top package; a bottom package having one surface and the other surface, the bottom package being formed under the top package and connected to the top package through the external connection terminals; and warpage preventing layers formed on one surface of the top package, the other surface of the top package, one surface of the bottom package, or the other surface of the bottom package.

The warpage preventing layer may be made of a cure shrinkable material.

The warpage preventing layer may be made of a resin.

The warpage preventing layer may be formed on the outermost layer of the top package or the bottom package.

The top package may include: a substrate; a semiconductor device mounted on the substrate; and a molding member formed on the substrate including the semiconductor device, and the warpage preventing layer may be formed on the molding member or beneath the substrate.

The bottom package may include: a substrate; and a semiconductor device mounted on the substrate, and the warpage preventing layer may be formed in a semiconductor device non-mounting region or beneath the substrate.

According to still another preferred embodiment of the present invention, there is provided a method for manufacturing a semiconductor package, including: preparing a substrate having one surface and the other surface; mounting a semiconductor device mounted on one surface of the substrate; forming external connection terminals on the other surface of the substrate; forming a warpage preventing layer formed on one surface of the substrate or the other surface of the substrate; and performing a reflow process on the substrate.

In the forming of the warpage preventing layer, the warpage preventing layer may be made of a cure shrinkable material in an uncured state.

In the forming of the warpage preventing layer, the warpage preventing layer may be made of an uncured resin.

In the forming of the warpage preventing layer, the warpage preventing layer may be formed on the outermost layer of the substrate.

The semiconductor package may be a flip chip chip scale package (FCCSP) type or a flip chip ball grid array (FCBGA) type.

The semiconductor package may be a package on package (POP) type.

### BRIEF DESCRIPTION OF THE DRAWINGS

FIG. 1 is a cross-sectional view showing a structure of a semiconductor package according to a first preferred embodiment of the present invention;

FIG. 2 is a cross-sectional view showing a structure of a top package in a semiconductor package according to a second preferred embodiment of the present invention;

FIG. 3 is a cross-sectional view showing a structure of a bottom package in the semiconductor package according to the second preferred embodiment of the present invention; and

FIG. 4 is a view illustrating a method for manufacturing a semiconductor package according to a preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the gist of the present invention. Terms used in the specification, ‘first’, ‘second’, etc., can be used to describe various components, but the components are not to be construed as being limited to the terms.

Hereinafter, preferred embodiments of the present invention will be described in detail with reference to the accompanying drawings.

### Semiconductor Package

### First Preferred Embodiment

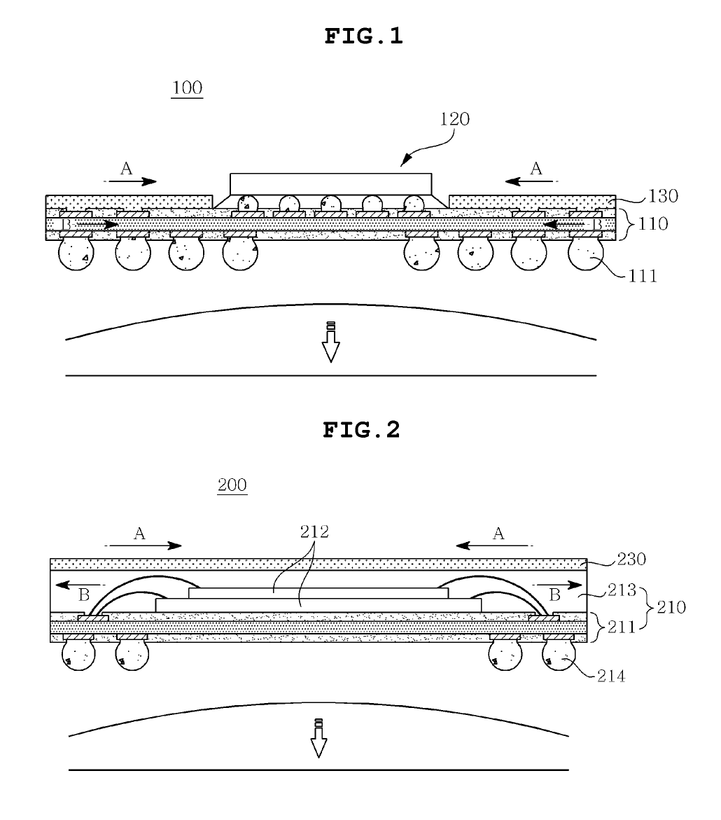

FIG. 1 is a cross-sectional view showing a structure of a semiconductor package according to a preferred embodiment of the present invention.

As shown in FIG. 1, a semiconductor package 100 may include a substrate 110 having one surface and the other surface, a semiconductor device 120 mounted on one surface of the substrate 110, external connection terminals 111 formed on the other surface of the substrate 110, and a warpage preventing layer 130 formed on one surface or the other surface of the substrate 110.

Here, the semiconductor package 100 may have a structure of flip chip chip scale package (FCCSP) or flip chip ball grid array (FCBGA), but is not limited thereto.

Also, the warpage preventing layer 130 may be made of a cure shrinkable material.

Also, the warpage preventing layer 130 may be made of a resin, but is not limited thereto. In other words, as the warpage preventing layer 130, any material that can be cure-shrunken through reflow may be employed.

Also, the warpage preventing layer 130 may be formed on the outermost layer of the substrate 110.

The warpage preventing layer 130 described in FIG. 1 may be formed in the semiconductor package by coating or laminating the cure shrinkable material. The warpage preventing layer 130 may be formed in a region of the semiconductor package in a contrary direction of where warpage occurs, thereby reducing warpage of the semiconductor package.

For example, as shown in FIG. 1, when the semiconductor package 100 is convexly warped, the warpage preventing layer 130 is formed on the substrate 110, which corresponds to an upper portion of the semiconductor package 100, to suppress warpage.

More specifically, the warpage preventing layer 130 is formed on the substrate 110 in an uncured state, and then cure shrinkage stress of resin is further applied to an upper portion of the substrate rather than a lower portion of the substrate at the time of reflow, thereby suppressing warpage of the semiconductor package.

In FIG. 1, “A” indicates a direction of the cure shrinkage stress at the time of reflow of the uncured resin, and “B” indicates a direction of stress with respect to a coefficient of thermal expansion (CTE) of the substrate.

### Semiconductor Package

### Second Preferred Embodiment

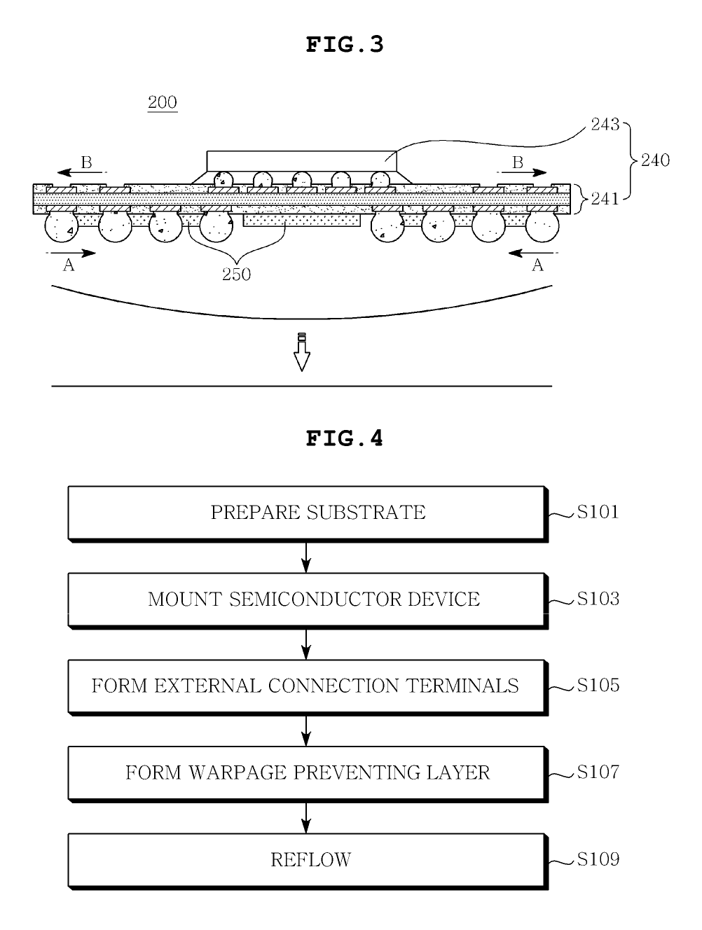

FIG. 2 is a cross-sectional view showing a structure of a top package in a package on package (POP) type semiconductor package according to a second preferred embodiment of the present invention and FIG. 3 is a cross-sectional view showing a structure of a bottom package in the package on package (POP) type semiconductor package according to the second preferred embodiment of the present invention.

However, in the second present preferred embodiment, a description for the same components as those of the first preferred embodiments will be omitted and a description only for components different therefrom will be provided.

As shown in FIGS. 2 and 3, a semiconductor package 200 may include a top package 210 having one surface and the other surface and including a semiconductor device 212 mounted thereon, external connection terminals 214 formed on one surface of the top package 210, a bottom package 240 having one surface and the other surface, the bottom package 240 being provided under the top package 210 and connected to the top package 210 through the external connection terminals 214, and warpage preventing layers 230 and 250 formed on one surface of the top package 210, the other surface of the top package 210, one surface of the bottom package 240, or the other surface of the bottom package 240.

Here, a case where the warpage preventing layers 230 and 250 are formed above the top package 210 and below the bottom package 240 shown in FIGS. 2 and 3 is taken as an example. However, without being limited thereto, the warpage preventing layers may be formed at regions of the semiconductor package, where warpage needs to be reduced, including the lower portion of the top package or the upper portion of the bottom package.

Also, the warpage preventing layers 230 and 250 may be made of a cure shrinkable material.

Also, the warpage preventing layers 230 and 250 may be made of a resin, but is not limited thereto. In other words, as the warpage preventing layers 230 and 250, any material that can be cure-shrunken through reflow may be employed.

Also, the warpage preventing layers 230 and 250 may be formed on the outermost layer of the top package 210 or the bottom package 240.

More specifically, the top package 210 may include a substrate 211, a semiconductor device 212 mounted on the substrate 211, and a molding member 213 formed on the substrate 211 including the semiconductor device 212.

Also, the warpage preventing layer 230 may be formed on the molding member 213 or beneath the substrate 211.

For example, as shown in FIG. 2, in general, the top package 210 of the semiconductor package 200 is convexly warped due to curing of a resin of the molding member and CTE shrinkage. However, the warpage preventing layer 230 is formed on the top package 210, which corresponds to an upper portion of the semiconductor package 200, to suppress warpage.

More specifically, the warpage preventing layer 230 is formed on the top package 210 in an uncured state, and then thermal expansion stress of epoxy molding compounds (EMC) and the substrate 211 are suppressed by cure shrinkage stress at the time of reflow, thereby suppressing warpage of the semiconductor package.

In FIG. 2, “A” indicates a direction of the cure shrinkage stress at the time of reflow of the uncured resin, and “B” indicates a direction of stress with respect to a coefficient of thermal expansion (CTE) of the substrate.

More specifically, the bottom package 240 also may include a substrate 241 and a semiconductor device 243 mounted on the substrate 241.

Here, the warpage preventing layer 250 may be formed in a semiconductor device non-mounting region on the substrate 241 or beneath the substrate 241.

For example, as shown in FIG. 3, in general, the bottom package 240 of the semiconductor package 200 is convexly warped since thermal expansion stress of the substrate is larger than the semiconductor device during a temperature fall period due to a difference in coefficient of thermal expansion between the semiconductor device 243 and the substrate 241. However, the warpage preventing layer 250 is formed under the bottom package 240, which corresponds to a lower portion of the semiconductor package 200, to suppress warpage.

More specifically, the warpage preventing layer 250 is formed under the bottom package 240 in an uncured state, and then thermal expansion stress of epoxy molding compounds (EMC) and the substrate 241 are suppressed by cure shrinkage stress at the time of reflow, thereby suppressing warpage of the semiconductor package.

In FIG. 3, “A” indicates a direction of the cure shrinkage stress at the time of reflow of the uncured resin, and “B” indicates a direction of stress with respect to a coefficient of thermal expansion (CTE) of the substrate.

Method for Manufacturing Semiconductor Package

FIG. 4 is a view illustrating a method for manufacturing a semiconductor package according to a preferred embodiment of the present invention. The method according to the present invention will be described with reference to FIG. 4 together with FIGS. 1 to 3.

First, as shown in FIG. 4, a substrate having one surface and the other surface may be prepared (S101).

Here, the substrate may be any one of the substrates for FCCSP, FCBGA, and POP package.

Next, a semiconductor device may be mounted on one surface of the substrate (S103).

Next, external connection terminals may be formed on the other surface of the substrate (S105).

Next, a warpage preventing layer may be formed on one surface or the other surface of the substrate (S107).

Here, the warpage preventing layers 130, 230, and 250 may be made of a cure shrinkable material in an uncured state.

Also, the warpage preventing layers 130, 230, and 250 may be made of an uncured resin.

Also, the warpage preventing layers 130, 230, and 250 may be formed on the outermost layer of the substrate.

Next, a reflow process may be performed on the substrate.

The semiconductor package formed by the above-described manufacturing process may be a flip chip chip scale package (FCCSP) type or a flip chip ball grid array (FCBGA) type, as shown in FIG. 1.

Also, as shown in FIGS. 2 and 3, the semiconductor package may be a package on package (POP) type.

In other words, the above-described substrate may be any one of the substrates for FCCSP, FCBGA, and POP package.

The above-described warpage preventing layers 130, 230, and 250 may be formed in the semiconductor package by coating or laminating the cure shrinkable material. The warpage preventing layers 130, 230 and 250 may be formed in a region of the semiconductor package in a contrary direction of where warpage occurs, thereby reducing warpage of the semiconductor package.

For example, as shown in FIGS. 1 to 3, the warpage preventing layers 130, 230 and 250 may be formed at an upper portion or a lower portion of the semiconductor package depending on the warpage type of the semiconductor package (for example, a convex type or a concave type), thereby suppressing warpage.

More specifically, the warpage preventing layers 130, 230, and 250 are formed on (or beneath) the substrate in an uncured state, and then the cure shrinkage stress of resin is further applied to an upper portion (a lower portion) of the substrate rather than a lower portion (an upper portion) of the substrate at the time of reflow, thereby suppressing warpage of the semiconductor package.

As set forth above, with the semiconductor package and the method for manufacturing the same according to the present invention, since the uncured resin is formed on the substrate of the semiconductor package and then a reflow process is performed, a warpage phenomenon occurring in the substrate and the semiconductor package at a high temperature can be reduced by cure shrinkage stress of resin.

Further, according to the preferred embodiments of the present invention, defects such as non-wetting or bump cracking occurring at the time of reflow can be reduced, resulting in an increase in yield.

Although the preferred embodiments of the present invention have been disclosed for illustrative purposes, they are for specifically explaining the present invention and thus a semiconductor package and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A semiconductor package, comprising:
a substrate having one surface and the other surface;
a semiconductor device mounted on one surface of the substrate;
external connection terminals formed on the other surface of the substrate; and
a warpage preventing layer formed on one surface or the other surface of the substrate.

2. The semiconductor package as set forth in claim 1, wherein the semiconductor package is a flip chip chip scale package (FCCSP) type or a flip chip ball grid array (FCBGA) type.

3. The semiconductor package as set forth in claim 1, wherein the warpage preventing layer is made of a cure shrinkable material.

4. The semiconductor package as set forth in claim 1, wherein the warpage preventing layer is made of a resin.

5. The semiconductor package as set forth in claim 1, wherein the warpage preventing layer is formed on the outermost layer of the substrate.

6. A semiconductor package, comprising:
a top package having one surface and the other surface and including a semiconductor device mounted thereon;
external connection terminals formed on one surface of the top package;
a bottom package having one surface and the other surface, the bottom package being formed under the top package and connected to the top package through the external connection terminals; and
warpage preventing layers formed on one surface of the top package, the other surface of the top package, one surface of the bottom package, or the other surface of the bottom package.

7. The semiconductor package as set forth in claim 6, wherein the warpage preventing layer is made of a cure shrinkable material.

8. The semiconductor package as set forth in claim 6, wherein the warpage preventing layer is made of a resin.

9. The semiconductor package as set forth in claim 6, wherein the warpage preventing layer is formed on the outermost layer of the top package or the bottom package.

10. The semiconductor package as set forth in claim 6, wherein the top package includes: a substrate; a semiconductor device mounted on the substrate; and a molding member formed on the substrate including the semiconductor device, and the warpage preventing layer is formed on the molding member or beneath the substrate.

11. The semiconductor package as set forth in claim 6, wherein the bottom package includes: a substrate; and a semiconductor device mounted on the substrate, and the warpage preventing layer is formed in a semiconductor device non-mounting region or beneath the substrate.

12. A method for manufacturing a semiconductor package, comprising:
preparing a substrate having one surface and the other surface;
mounting a semiconductor device mounted on one surface of the substrate;
forming external connection terminals on the other surface of the substrate;
forming a warpage preventing layer formed on one surface of the substrate or the other surface of the substrate; and
performing a reflow process on the substrate.

13. The method as set forth in claim 12, wherein in the forming of the warpage preventing layer, the warpage preventing layer is made of a cure shrinkable material in an uncured state.

14. The method as set forth in claim 12, wherein in the forming of the warpage preventing layer, the warpage preventing layer is made of an uncured resin.

15. The method as set forth in claim 12, wherein in the forming of the warpage preventing layer, the warpage preventing layer is formed on the outermost layer of the substrate.

16. The method as set forth in claim 12, wherein the semiconductor package is a flip chip chip scale package (FCCSP) type or a flip chip ball grid array (FCBGA) type.

17. The method as set forth in claim 12, wherein the semiconductor package is a package on package (POP) type.
